(19) United States
(12) Patent Application Publication
(10) Pub. No.: US 2004/0022028 A1
(43) Pub. Date: Feb. 5, 2004

(54) Apparatus and system for cooling electric circuitry, integrated circuit cards, and related components

(76) Inventor: James J. Hildebrandt, North Truro, MA (US)

Correspondence Address: Thomas Kahrl, Box 1177, West Falmouth, MA, 02574, US

(21) Appl. No.: 10/376,211

(22) Filed: Feb. 27, 2003

Related U.S. Application Data
(63) Continuation-in-part of application No. 09/974,335, filed on Oct. 10, 2001, now Pat. No. 6,552,901.
Application No. 09/974,335 is a continuation-in-part of application No. 09/465,428, filed on Dec. 21, 1999, now Pat. No. 6,313,992.
(60) Provisional application No. 60/113,332, filed on Dec. 22, 1998.

(51) Int. Cl. H05K 7/20

(52) U.S. Cl. 361/700

(57) ABSTRACT

The present invention relates to a significantly more effective method and apparatus for the removal of latent heat from integrated circuit boards. A significant increase in power density is achieved by utilizing the enclosure of an electronics package for spraying liquids onto integrated circuit boards and their components and associated heat sinks. The enclosure becomes a plenum or the injection source in the spray cooling process. In this manner cooling fluid can be supplied to the panels of the case housing of the electronic components

### CLAIM FOR BENEFIT AND PRIORITY

This application is a continuation-in-part application and claims the benefit of and priority from U.S. application Ser. No. 09/974,335 filed Oct. 10, 2001 which is a continuation-in-part application that claims the benefit of and priority from U.S. application Ser. No. 09/465,428 filed Dec. 21, 1999 now U.S. Pat. No. 6,313,992 which claimed the benefit of and priority from U.S. Provisional Application No. 60/113,332 filed Dec. 22, 1998.

### BACKGROUND OF THE INVENTION

1. Field of the invention

This invention relates generally to the cooling of electronic circuitry, integrated circuit boards, and their components to increase their power density. Most electrically energized equipment is limited in its capacity by thermal constraints. To an increasing degree, the future viability of more-electric ships, cars, trucks, aircraft, spacecraft and trains is becoming more dependent upon novel thermal management designs, which can positively impact weight, cost, reliability and performance. In a related emerging area, thermal management will also be critical to the implementation and improved success of micro and sub-micro molecular or biological devices and MEMS (Micro Electronic Mechanical Devices). Thermal optimization of integrated biological and nano-structure electronic devices, which the inventor refers to as “biolectronic” devices, will be vital to improve power density and expansion of the electronics market.

It is essential that these various electronic devices be provided with effective thermal management systems to attain a specific state of electron, cellular, and intra-molecular activities and/or a desirable metabolism. The performance capabilities of such devices can be severely limited and/or subject to high failure rates due to an inability to operate within their optimal thermal range. This deficiency in thermal management could also have a direct effect on the efficiency, power density and, ultimately, the value of emerging technologies such as biolectronic devices.

Each year additional software and hardware is required by electronic systems in order to meet customer expectations, particularly in computing and power electronics. Increasingly there are many applications where significantly higher power is required and space is at a premium. Efficiency and power density may be compromised by the addition of more cumbersome integrated circuit cooling systems utilizing cold plates and traditional spray cooling methods. There are many applications where power density is not a significant issue, however, there are an increasing number of applications, environments and uses, such as utilization of commercially available off-the-shelf integrated circuit boards, which are now being spray cooled. This is an effort to adapt the boards' packaging as opposed to the boards themselves. These air-cooled boards often require higher packaging densities with utilization in mobile/dynamic applications when they were originally intended for stationary environments. Thermal attributes and power density must be optimized to enable such applications to be effectively implemented.

One such example is the current interest in the introduction of hybrid/electric propulsion systems of transportation. Power density is a critical factor in determining overall fuel efficiency of the platform. It is critical to reduce an electrical component's size to achieve lightweight, cost-effective components implemented into cost effective modes of transportation.

The present invention relates to a significantly more effective method and apparatus for the removal of latent heat from integrated circuit boards. I have found that a significant increase in power density is achieved by utilizing the enclosure of an electronics package for spraying liquids onto integrated circuit boards and their components and associated heat sinks. The enclosure becomes a plenum or the injection source in the spray cooling process.

By controlling the temperature of the integrated circuit boards in accordance with the principles of the invention, there are several advantages. First, the working fluid provides conductive cooling to the enclosure. Second, the working fluid reduces electromagnetic interference (“EMI”), and thirdly, protects the electronic components contained within the case from radiation. Such protection is particularly useful when such cases are constructed of composite materials for weight savings and strength. Finally, use of the invention results in the optimum placement of spray nozzles and injectors by incorporating them into the case itself. Poorly placed spray apparatus, utilized to nebulize liquids inside the electronics enclosure, contributes to a system's thermal boundary complexity, requires more space and adds additional cost.

2. Description of Related Art

U.S. Pat. No. 6,313,992 (“Hildebrandt”) Method and Apparatus for Delivering Fluid to the Interior and Surface of a Semiconductor Component or its Board. The present invention may function in combination with the invention disclosed in this patent and provide a source of cooling fluid by delivering cooling fluid to such a device via its enclosure.

U.S. Pat. No. 5,777,384 (“Root”) Method for Cooling Semiconductor Devices. Spray nozzles are placed over the components independent of the enclosure.

U.S. Pat. No. 4,897,762 (“Diakoku”) Cooling System and Method for Cooling Electronic Circuit Devices. Patent discloses a method for passing an air/coolant mixture adjacent to a spray-cooled device.

U.S. Pat. No. 5,818,692 (“Denny”) Apparatus and Method for Cooling an Electronic Component. Cooling fluid is delivered via a wire to electronic components. The sheath of a wire for an electronic component provides for a channel to deliver cooling fluid as part of a traditional closed loop system.

U.S. Pat. No. 5,749,444 (“Tilton”) Packaging and Cooling System for Power Semiconductor. This patent provides for a modification to integrated circuit components, such as a semiconductor module. Traditional fluid disbursement is utilized inside the case via nozzles.

U.S. Pat. No. 5,998,240 (“Hamilton”) Method and Apparatus for Controlling Electrostatic Coupling to Plasmas. Patent discloses a method for configuring semiconductors with fluid carrying channels on their surface to aid in distribution of cooling fluid. The use of channels increases the surface area of the components and has no effect on the fluid delivery.

U.S. Pat. No. 5,880,931 (“Tilton”) Spray Cooled Circuit Card Cage. This apparatus is utilized with a system of nozzles attached to a rear back plane of the enclosure. Requires additional space between cards in the enclosure. This patent uses a system of spray nozzles independent of the back plate of an enclosure. Furthermore, the enclosure does not provide a means of fluid for delivery to the electronics.

U.S. Pat. No. 5,131,233 (“Cray”) Gas Liquid Forced Turbulence Cooling. This patent discloses a liquid cooled circuit package where the cooling fluid is either sprayed onto the package or the package is immersed in a cooling liquid during operation. All cooling ports are internal to the enclosure and are not an integral part of the enclosure.

None of the foregoing prior art suggested nozzles, ports, perforations or passageways in the enclosure fascia itself. Furthermore, the previously mentioned prior art does not disclose a fluid delivery system as described herein.

### SUMMARY OF THE INVENTION

The present invention provides a method and apparatus for addressing a significant obstacle in increasing power density of integrated circuit boards and their components during the delivery of cooling liquids in the spray cooling or heating process.

Substantial inefficiencies occur in traditional systems that attempt to remove latent heat from energized circuit board components. One system is the traditional closed loop spray cooling process. In such traditional systems, nozzles or injectors typically are placed around the interior of a sealed enclosure such as a VME case. The nozzles are placed adjacent to a board or attached to the side of the case and located in the proximity of the energized components.

A second arrangement is shown by U.S. Pat. No. 6,313,992 by Hildebrandt that shows the boards or components themselves acting to deliver the cooling media. In both arrangements, the perforations, nozzles or injectors are not integral with or formed by the enclosure itself.

Once the fluid is applied pursuant to one of the arrangements described above, the cooling fluid evaporates removing heat from the circuit board and its components. In the typical closed loop system, the fluid is delivered via nozzles or injectors that are a part of the cooling apparatus located inside of an enclosure and are not part of the enclosure itself.

In the present invention, cooling fluid is supplied to the panels of the case housing of the electronic components. Such electronic components may be integrated circuit boards, power supplies, heat sinks, or any other electronics that may be housed in an enclosure. The enclosure panels are provided with internal passageways and may be connected to nozzles, ports, or injectors. Such nozzles, atomizers, ports, or injectors may be formed from case panels themselves. Alternatively, such nozzles, atomizers, ports, or injectors may be supplied with fluid by the passageways within the case panels.

In one embodiment of the invention, the cooling fluid, capable of phase change, passes through the passageways and exits through ports or nozzles on the inner surface on the integrated circuit board or power electronics enclosure. Thus, the enclosure will benefit from conductive cooling as the fluid passes through the core of the case panels. Furthermore, the present invention may provide protection from cross-EMI, which might otherwise interfere with adjacent electronics. In addition, if a dielectric fluid is used, it will provide protection from air or space borne radiation. The components within the case may be cooled by evaporative cooling as the liquid changes phase on or near surface of the component, circuit board, or heat sink. Additionally, the components may be conductively cooled with a single-phase fluid delivery composition.

More traditional spray-cooling designs have to overcome a multitude of obstacles. One significant obstacle results from the placement of spray nozzles in the interior of such an electronic case. Since one of the primary objectives of utilizing this type of cooling is to increase power density, all necessary steps should be taken to avoid unnecessary cooling components amongst the electronics. The inclusion of traditional separate spray nozzles and the traditional means for supplying cooling fluid thereto results in the inclusion of multiple additional components in and amongst the electronics.

Standardization is also becoming an important issue. Part counts can be reduced considerably by utilizing the panels of the enclosure itself as a means for supplying cooling fluid or for an injection plane. Ultimately, this provides for a manufacturing economy of scale by its effective use of one component part for multiple purposes. The multiple uses of single component parts may reduce the total number of component parts in a given system thereby reducing total manufacturing costs and complexity. One additional net effect may be increased power density.

One embodiment of the present invention can be carried out in a manner where a continuous supply of liquid coolant is provided to one or more surfaces of a six-sided enclosure. Of course, the principles of the present invention may be applied to any number of sides or surfaces of an enclosure that has any number of sides or surfaces. In the case of a conventional six-sided enclosure, one side, typically the back plane, generally carries multiple card slots. The slots carry electric current, which can create a substantial part of the heat generated in a given system. This side of the enclosure generally creates the most heat due to the power buss infrastructure integrated therein. By modifying this side in accordance with the principals of the invention, the card slots may be conductively and/or evaporatively cooled. For example, by providing passageways that carry cooling fluid within the back plane, the back plane and card slots may be conductively cooled. In addition, outlets such as ports, nozzles, or injectors may be connected to the passageways to provide for evaporative cooling.

The cooling fluid may change phases at any point in the system. For example, the cooling fluid may evaporate within the passageways in the core of the plate. If so, some nozzles, outlets or injectors may function mainly to allow partially vaporized cooling fluid to escape from the passageways. Alternatively, the fluid may be liquid when it is sprayed from the nozzles, outlets, or injectors. In such a case, the nozzles, outlets, or injectors may be adapted to spray the cooling fluid onto or towards electronic components. Thus, the cooling fluid may change phase on or near the surface of such electronic components.

Some or all of the principles of the present invention may be used in conjunction with perforated electronic components, heat sinks, and circuit boards such as those described in U.S. Pat. No. 6,313,992 and U.S. patent application No. 09/974335. The disclosures and teachings of those documents and their file histories are hereby incorporated herein by reference. Those documents teach, among other things, that a circuit board may be provided with one or more internal passageways for carrying cooling fluid. The peripheral edges of the board may be joined and sealed creating a void or chamber with a sandwich-like enclosure to act as a plenum or manifold for liquid coolants.

An enclosure constructed in accordance with the principles described above may be further adapted to mate with and supply cooling fluid to such a circuit board, or any other perforated component or item as taught in the previously mentioned documents. The fluid is not limited to delivery through a single portal. Multiple portals or flooding of the enclosure that surrounds the pins and connectors may be implemented to cool the contacts. In addition to performing a cooling or heating function, the cooling fluid may wash or clean the contacts and components removing foreign conductive elements that may interfere with the proper functioning of the electronics contained within the enclosure. Said conductive elements may contribute to static build-up and subsequent discharge amongst components and/or to component infrastructure. Fluid may flow to the outside of the connector to cool the frame of the connector for the pins. Additionally, the pins themselves may be adapted to function as fluid conduits. A multitude of any combination of these methods can be employed to best suit a user.

Interconnecting ports or connectors may be sealed with an “o ring”, gasket, or other sealing means sufficient to maintain a desired pressure to said connector. IC boards or other individual electronic components may be connected to one another through fluid ports thus, allowing the fluid to flow through varying panels of which the enclosure is comprised. For example, a card cage may be mounted to interior face A and an electronic component such as a power semi conductor device, which may be mounted to interior face B. These two electronic parts may have independent power supplies but share a common fluid source, which is integral to the enclosure. The fluid source may be via panel A, which in turns supplies panel B which then services panel C etc. An infinite array of passages can be designed based on the requirements of the system. Alternatively, the fluid may be delivered independently to one or more enclosure panels. This would enable a user to select an infinite array of pressures. One or more of the enclosure panels may be used for fluid or vapor collection as opposed to fluid delivery.

A second factor that may influence the fluid delivery and pick-up designs is the type of environment the enclosure is operating in. For example, an enclosure that is expected to operate primarily on the ground may vary from one expected to primarily operate in a subsurface environment, air or in space. The differential core temperature of one side of the enclosure as compared to another can mobilize vaporized fluid towards a heat exchanger or prescribed cooling surface for a given application or operating environment. The differential core temperature can induce varying pressures or a vacuum to mobilize liquid or vapor.

Some or all of the principles of the present invention may also be used to maintain a desirable microclimate for the interior of an enclosure. One such example is to provide heat in excessively cold environments. The hermetically sealed enclosure acts as a sort of mini “clean room” environment, which affords safe operation of many sensitive electronics that tend to attract conductive foreign particulates that can contribute to adverse conditions such as static build-up. This protection alone offers an advantage over air-cooled devices. Particulate accumulation also fosters EMI amongst integral componentry. Changes in emmisivity make it nearly impossible to mitigate problems in advance with the lack of a self-cleansing enclosure. Maintaining stable resistance and a constant conductive environment are paramount to consistent semi conductor activity. This is of particular importance in sensitive communication and orientation devices such as satellites, radar, laser, lidar, sonar, transceivers and receivers.

An enclosure constructed in accordance with the principles of the invention may provide an effective shield against radiation given the stable dielectric nature of many coolants. The fluid may be continuously run through an irradiation device to mitigate cumulative damage. This aspect of the invention may be particularly useful in the propagation of composite cases.

The improved cooling of the back plane of an enclosure constructed in accordance with the principles of the invention also may increase the overall carrying capacity of the conductive infrastructure, including the buss, by providing efficient cooling and a more uniform temperature with a simple, more unified transition of heat removal. This novel technique can also be used in other applications to maintain a desired operational temperature range. As described above, in at least one embodiment, both conductive and/or evaporative cooling may result.

Construction methods for constructing the internal passageways and integral nozzles are well known in the art and include such methods as, without limitation, masking, etching, lithography, vapor deposition, sputtering, laser techniques, cellular, atomic and molecular formation, molding, forming, and extrusion.

The aforementioned objects and advantages of the present invention, as well as additional objects and advantages thereof, will be more fully understood from the following detailed description of the preferred embodiments when taking in conjunction with the following drawings. It should be understood, however, that the detailed description and the specific examples while representing the preferred embodiments are given by way of illustration only and should not be construed in a limiting sense.

### BRIEF DESCRIPTION OF THE DRAWINGS

FIG. 1 is a cutaway perspective view of the interior of an enclosure constructed in accordance with the principles of the present invention.

FIG. 2 is a cutaway view of a portion of an enclosure panel constructed in accordance with the principles of the present invention showing internal passageways within the panel and attached spray nozzles.

FIG. 3 is a cutaway view of a portion of an enclosure panel constructed in accordance with the principles of the present invention showing internal passageways within the panel and spray nozzles formed from and integral with the inner layer of the panel.

FIG. 4 is a cutaway view of a portion of an enclosure panel constructed in accordance with the principles of the present invention comprising three layers and showing internal passageways within the panel and spray nozzles formed from and integral with the inner layer of the panel.

FIG. 5 is a cutaway perspective view of a portion of an enclosure panel constructed in accordance with the principles of the present invention showing internal passageways within the panel and showing one possible arrangement of spray nozzles on the inner surface of the panel.

FIG. 6 is a perspective view of a multi-pin slot constructed in accordance with the principles of the present invention showing an integrated circuit board with a cooling fluid connection to the back plane.

### DETAILED DESCRIPTION OF PREFERRED EMBODIMENTS

The following description is of the best presently contemplated modes of carrying out the invention. This description is made for the purpose of illustrating the general principles of the invention and should not be taken in a limiting sense.

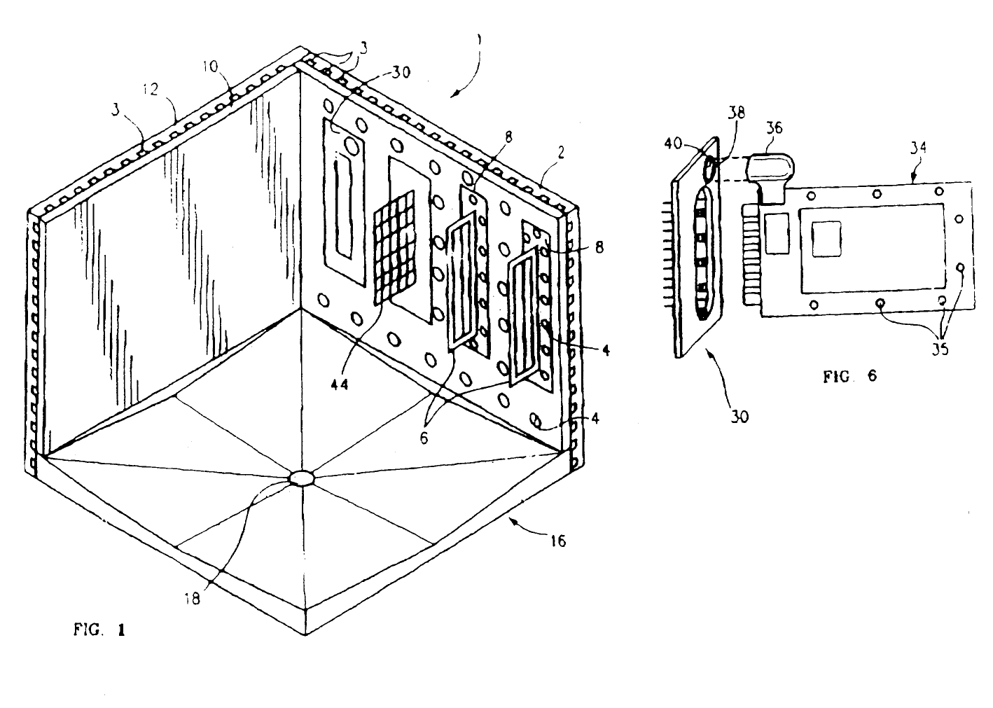

In accordance with the principles of the present invention, FIG. 1 shows three panels of a six-sided enclosure designated generally 1. The back plane 2 is provided with internal passages 3 connecting to nozzles or injectors 4. Integrated circuit boards 6 are attached to a multi-pin connectors 8 located on the back plane 2. The multi-pin connectors may also be provided with internal passages (not shown) connecting with nozzles or injectors 4 on the surface of multi-pin connectors 8.

The enclosure wall may be constructed of one, two, or more layers. FIG. 1 shows a wall constructed with an inner layer 10 and an outer layer 12. The inner layer 10 may be utilized for forming, imbedding, or attaching nozzles or injectors 4. The outer wall 12 may be provided with one or more passages 3 to hold cooling liquid and supply such liquid to nozzles or injectors 4. Alternatively, the outer wall 12 may be solid and the inner layer 10 may be provided with one or more internal passages 3 and integral or attached nozzles or injectors 4. One or more of the enclosures walls such as wall 16 may include outlets ports 18 for the evacuation of gas and/or fluid.

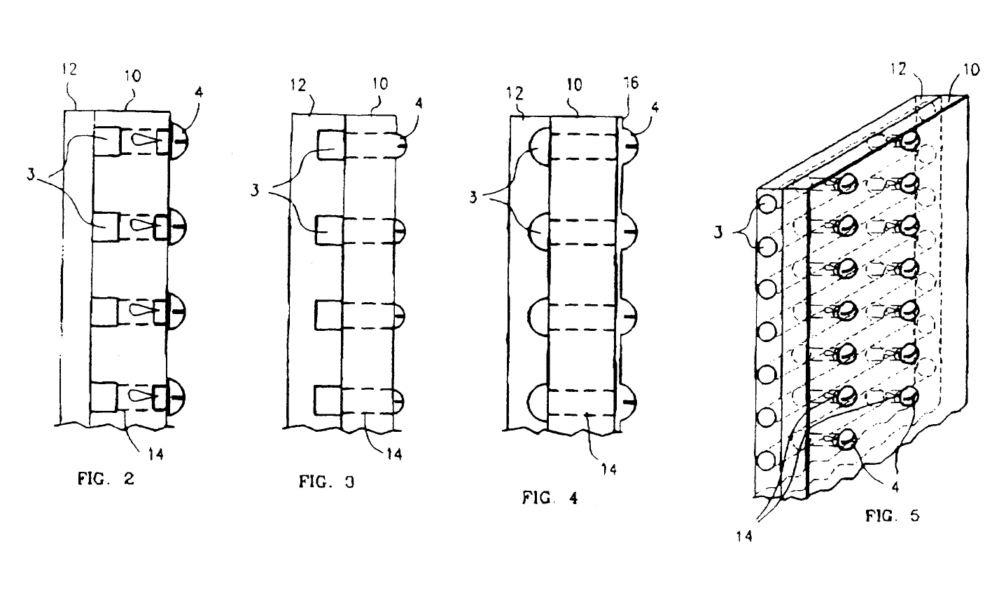

FIGS. 2, 3 and 4 show cross-sectional detail views of three different embodiments of enclosure walls constructed in accordance with the principles of the invention. As shown in FIG. 2, outer wall 12 may be solid and inner wall 10 may be provided with one or more internal passageways 3 for holding and supplying cooling fluid. As shown in FIGS. 3 and 4, internal passageways 3 may be located in outer layer 12 and may be a variety of cross-sectional shapes.

Inner layer 10 may further be provided with one or more ports or passages 14 allowing fluid to pass from internal passageways 3 into the interior of enclosure 1. As shown in FIG. 2, nozzles 4 may be separate components connected to one end of ports or passages 14. Alternatively, nozzles, sprayers, injectors or ports 4 may be formed from and integral with the inner surface of inner layer 10 as shown in FIG. 3. FIG. 4 shows a third embodiment wherein nozzles, sprayers, injectors or ports 4 are formed from an additional layer 16 that overlays inner layer 10. Note that an enclosure wall may be constructed from any number of layers, including only one layer.

FIG. 5 shows a perspective internal view of one embodiment of an enclosure wall constructed in accordance with the principles of the present invention. FIG. 5 shows the relationship between internal passageways 3, ports or passages 14 and nozzles, sprayers, injectors or ports 4. FIG. 5 also shows one possible array of nozzles, sprayers, injectors or ports 4. Alternatively, nozzles, sprayers, injectors or ports 4 may be located to direct fluid into specific components.

The foregoing examples are provided merely to illustrate various embodiments of the principles of the invention. Accordingly, the scope of the invention is not intended to be limited to the embodiments depicted in FIGS. 2, 3, 4 and 5.

The working fluid may be supplied under pressure generated by a pump or other known means. Alternatively, the system may function as a heat pump, requiring no moving parts.

FIG. 6 is a perspective view of a multi-pin slot 30 attached to the back plane 2 of enclosure 1. A perforated integrated circuit board 34 is provided with a fluid coupling 36 adapted to mate with the receiver 38. Receiver 38 is provided with an “o ring” 40 to seal coupling 36 to receiver 38 and prevent fluid from leaking. Circuit board 34 may be attached to multi-pin slot 30 by a mechanical latch (not shown). Fluid passes from back plane 32 into circuit board 34 and out of ports 35 located on circuit board 34.

As shown in FIG. 1, any electronic component such as component 44 could be mounted to the back plane 2 of an enclosure constructed in accordance with the principles of this present invention. Rather than cooling through conductive and evaporative cooling such as illustrated by circuit board 34, component 44 may be cooled solely by conductive cooling by liquid passing from back plane 32 through the core of component 44 and back into back plane 32.

Any number of items may be attached to multi-pin slot 30 and supplied with cooling fluid. Such items may include, without limitation, a heat sink, power supply, microprocessor, DC-to-DC converters IGBT, SCR or other power semiconductor device.

It is important to note that the specific design of any enclosure constructed in accordance with the principles of the present invention may vary depending on the requirements of the specific application to which the invention is applied. For example, placement of nozzles, injectors and boards may vary widely depending upon the amount of heat generated in a specific location within an enclosure. An additional use may include the use of cards, which contain their own nozzles or injectors. In that case a particular section of an enclosure may be used to supply fluid to these cards and may or may not have intake or exhaust perforations on the innermost walls themselves.

One reasonably skilled in the art will appreciate that many alternate placement of nozzles may be used to effectively deliver or remove liquid or vapor from the interior surfaces of the enclosure. The seemingly endless array of nozzles and injectors placed on the innermost walls can direct fluid or vapor in virtually any direction including directly down onto heat sinks, components, circuit boards, or dies. The use of secondary or tertiary fluids may be used to propagate condensation or to pre-cool or preheat the working liquid. They may also be used to control the interior temperature of the case enclosing the electronics.

The apparatus of the subject system may include generally utilized components such as radiators, intercoolers or compressors, as well as filters, pumps and regulators, which are not shown but are generally known within the art.

The embodiments of the invention described above are cost-effective, production-oriented enclosures that may accept a variety of injectors and atomizers. A superior thermal equilibrium, amongst electronic components, molecular substrates and inter-cellular devices, may be achieved within such enclosures. This novel design may allow for a cost-effective way to the match fluid and gaseous flow rates with a simplified porting technique.

Although the invention has been described herein with references to specific embodiments, many modifications and variations therein will readily occur to those skilled in the art. Accordingly, all such variations and modifications are included within the intended scope of the invention.

1. An enclosure for holding electronic components comprising:
at least one wall;
said wall provided with at least one internal space for holding liquid.

2. An enclosure according to claim 1 wherein said internal space connects with at least one opening in said wall to allow liquid to pass from said internal space into the interior of said enclosure.

3. An enclosure according to claim 2 wherein at least one component selected from the following list is connected to said at least one opening: spray nozzles, atomizers, injectors or ports.

4. An enclosure according to claim 3 wherein said at least one component is formed from said wall.

5. An enclosure according to claim 1 wherein said wall is comprised of at least two layers.

6. An enclosure according to claim 2 wherein said wall is comprised of at least two layers.

7. An enclosure according to claim 3 wherein said wall is comprised of at least two layers.

8. An enclosure according to claim 7 wherein at least one component selected from the following list is formed from an innermost layer of said at least two layers: spray nozzles, atomizers, injectors, or ports.

9. An enclosure according to claim 4 wherein said wall is comprised of at least two layers.

10. An enclosure according to claim 1 further comprising at least one multi-pin slot attached to at least one wall of said enclosure
said multi-pin slot having at least one internal space for holding fluid.

11. An enclosure according to claim 10 wherein said internal space of said multi-pin slot is in communication with said internal space of said wall to allow fluid to pass between said internal space in said wall and said internal space in said multi-pin slot.

12. An enclosure according to claim 10 wherein said multi-pin slot defines at least one opening in a surface of said multi-pin slot;
said at least one opening in communication with said at least one internal space of said multi-pin slot to allow fluid to pass from said at least one internal space of said multi-pin slot through said at least one opening into the interior of said enclosure.

13. An enclosure according to claim 12 wherein said at least one opening comprises one or more of the following: spray nozzle, atomizer, injector or port formed from said multi-pin slot.

14. An enclosure according to claim 12 wherein said at least one opening is adapted to receive one or more of the following: spray nozzle, atomizer, injector or port.

15. An enclosure according to claim 10 further comprising at least one receiver in communication with said internal space of said multi-pin slot and adapted to mate with a coupling to supply fluid to said coupling.

16. An enclosure according to claim 10 further comprising at least one receiver in communication with said internal space of said wall;
said at least one receiver adapted to mate with a coupling to supply fluid to said coupling.

17. An enclosure according to claim 1 further comprising at least one receiver in communication with said internal space of said wall;
said at least one receiver adapted to mate with a coupling to supply fluid to said coupling.

18. An enclosure according to claim 1 wherein said enclosure and said internal space are adapted to supply fluid to an electronic device.

19. An enclosure according to claim 1 wherein said enclosure and said internal space are adapted to supply fluid to a radiator.

20. An enclosure according to claim 1 wherein said enclosure and said internal space are adapted to supply fluid to one or more heat exchangers.

21. An enclosure according to claim 1 wherein said enclosure and said internal space are adapted to supply fluid to one or more thermal plates.

22. An enclosure according to claim 1 wherein said enclosure and said internal space are adapted to supply fluid to one or more electronic components.

23. An enclosure according to claim 10 wherein said multi-pin slot is adapted to supply fluid to one or more pin connections of said multi-pin slot.

24. An enclosure according to claim 23 wherein said multi-pin slot is adapted to supply fluid to a circuit board capable of accepting fluid through one or more pin connections between said circuit board and said multi-pin slot.

25. An enclosure for holding electronic components having at least one wall comprising:
at least one multi-pin slot attached to at least one wall;
said multi-pin slot having at least one internal space for holding fluid.

26. An enclosure according to claim 25 wherein said multi-pin slot defines at least one opening in surface of said multi-pin slot;
said at least one opening in communication with said at least one internal space of said multi-pin slot to allow fluid to pass from said at least one internal space of said multi-pin slot through said at least one opening into the interior of said enclosure.

27. An enclosure according to claim 26 wherein said at least one opening comprises one or more of the following: spray nozzle, atomizer, injector or port formed from said multi-pin slot.

28. An enclosure according to claim 26 wherein said at least one opening is adapted to receive one or more of the following: spray nozzle, atomizer, injector or port.

29. An enclosure according to claim 25 further comprising at least one receiver in communication with said internal space of said multi-pin slot and adapted to mate with a coupling to supply fluid to said coupling.
